(19) United States
(12) Patent Application Publication
(10) Pub. No.: US 2017/0090632 A1
(43) Pub. Date: Mar. 30, 2017

(54) ORGANIC LIGHT EMITTING DISPLAY DEVICE AND METHOD FOR MANUFACTURING THE SAME

(71) Applicant: EVERDISPLAY OPTRONICS (SHANGHAI) LIMITED, SHANGHAI CITY (CN)

(72) Inventors: Wei Sheng SU, SHANGHAI CITY (CN); Jr-Hong CHEN, SHANGHAI CITY (CN)

(73) Assignee: EVERDISPLAY OPTRONICS (SHANGHAI) LIMITED, SHANGHAI CITY (CN)

(21) Appl. No.: 15/133,702

(22) Filed: Apr. 20, 2016

(30) Foreign Application Priority Data
Sep. 25, 2015 (CN) 201510618243.6

(51) Int. Cl. G06F 3/041; H01L 51/52; H01L 27/32

(52) U.S. Cl. CPC G06F 3/0412; H01L 27/323; H01L 27/3244; H01L 51/524; G06F 3/0414; H01L 2251/5338; H01L 2227/323; G06F 2203/04103

(57) ABSTRACT

The present disclosure relates to an organic light emitting display (OLED) device and a method for manufacturing the same, and an electronic apparatus employing the OLED device. The OLED device according to the present disclosure includes a touch screen, a display panel, a flexible circuit board and a plurality of pressure sensors. A lower surface of the display panel is applied with an adhesive layer, an upper layer of the flexible circuit board is adhered to the adhesive layer, and the plurality of pressure sensors are disposed in the adhesive layer. According to the OLED device of the present disclosure, pressure sensors are provided under the display panel with a simple structure without occupying the frame position of the cover glass.

### CROSS-REFERENCE TO RELATED APPLICATIONS

This application is based upon and claims priority to Chinese Patent Application 201510618243.6, filed on Sep. 25, 2015, the entire contents of which are incorporated herein by reference.

### TECHNICAL FIELD

The present disclosure relates to an organic light emitting display (OLED) device and a method for manufacturing the same, and an electronic apparatus employing the OLED device.

### BACKGROUND

Recently, since the development of a new generation touching technology, i.e., the touch sensing technology, the touching devices may sense the force of a light press and a hard press and activate different functions correspondingly.

However, in the current touching devices, pressure sensors are generally disposed under four corners of a cover glass to judge a magnitude of the force and the direction and position of the applied force. However, such a product is disadvantageous in that it is impossible to narrow frames of the product and other processes are required for the mechanism design.

### SUMMARY

One aspect of the present disclosure provides an organic light emitting display (OLED) device including: a touch screen; a display panel having an upper surface attached to a lower surface of the touch screen and a lower surface applied with an adhesive layer; a flexible circuit board having an upper surface adhered to the adhesive layer; and a plurality of pressure sensors disposed in the adhesive layer.

Another aspect of the present disclosure provides a method for manufacturing an organic light emitting display (OLED) device, the method including: in a step 1A, providing a flexible circuit board and a plurality of pressure sensors, and adhering the plurality of pressure sensors to an upper surface of the flexible circuit board; in a step 1B, providing a touch screen and a display panel, and attaching a lower surface of the touch screen to an upper surface of the display panel; in a step 1C, applying an adhesive layer at a lower surface of the display panel; and in a step 2, adhering an upper surface of the flexible circuit board to a lower surface of the adhesive layer with the plurality of pressure sensors imbedded into the adhesive layer.

A further aspect of the present disclosure provides an electronic apparatus including the above OLED device.

### BRIEF DESCRIPTION OF THE DRAWINGS

FIG. 1 is a cross sectional structural diagram of an OLED device of embodiment 1 of the present disclosure;

FIG. 2 is a top structural diagram of the OLED device of embodiment 1 of the present disclosure;

FIG. 3 is a schematic diagram of step 1A of a method for manufacturing the OLED device of embodiment 1 of the present disclosure;

FIG. 4 is a schematic diagram of step 1C of the method for manufacturing the OLED device of embodiment 1 of the present disclosure;

FIG. 5 is a schematic diagram of step 2 of the method for manufacturing the OLED device of embodiment 1 of the present disclosure; and

FIG. 6 is a cross sectional structural diagram of an OLED device of embodiment 2 of the present disclosure.

### DETAILED DESCRIPTION

Example implementations will now be described more fully with reference to the accompanying drawings. However, the example implementations can be implemented in various forms, and should not be interpreted as being limited to the implementations set forth herein; on the contrary, these implementations are provided such that the present disclosure will be thorough and complete, and will fully convey the concept of the example implementations to those skilled in the art. In the drawings, the same reference numerals denote the same or like structures, and thus their repeated description will be omitted.

The described features, structures or characters may be combined in one or more implementations in any suitable manner. In the following description, numerous specific details are provided so as to allow a full understanding of the implementations of the present disclosure. However, those skilled in the art will recognize that the technical solutions of the present disclosure may be implemented without one or more of the specific details, or other methods, components, materials and so on may be used. In some cases, the well-known structures, materials or operations are not shown or described in detail to avoid obscuring the present disclosure.

Drawings of the present disclosure are provided for illustrating relative position relations and electrical connection relations only, the thickness of the layers at some portions are exaggerated for ease of understanding, and the thickness in the drawings does not indicate actual scale of the thickness of layers.

### Embodiment 1

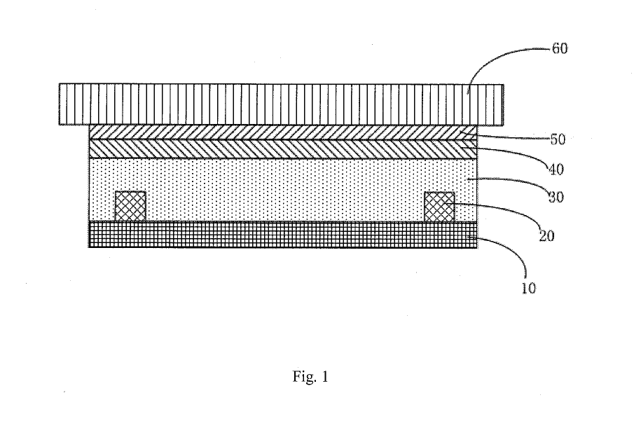

Referring to FIG. 1, which is a structural diagram of an OLED device of embodiment 1 of the present disclosure. The OLED device includes a touch screen 50, a display panel 40, an adhesive layer 30, a flexible circuit board 10 and a plurality of pressure sensors 20.

In the embodiment, an upper surface of the display panel 40 is attached to a lower surface of the touch screen 50. A lower surface of the display panel 40 is applied with the adhesive layer 30. An upper surface of the flexible circuit board 10 is adhered to the adhesive layer 30. The plurality of pressure sensors 20 are disposed in the adhesive layer 30.

In the present embodiment, a transparent cover plate 60 is disposed on the touch screen 50. The transparent cover plate 60 may be formed of glass, acryl or the like, but is not limited thereto.

Preferably, as illustrated in FIG. 1, the plurality of pressure sensors 20 are adhered to the upper surface of the flexible circuit board 10.

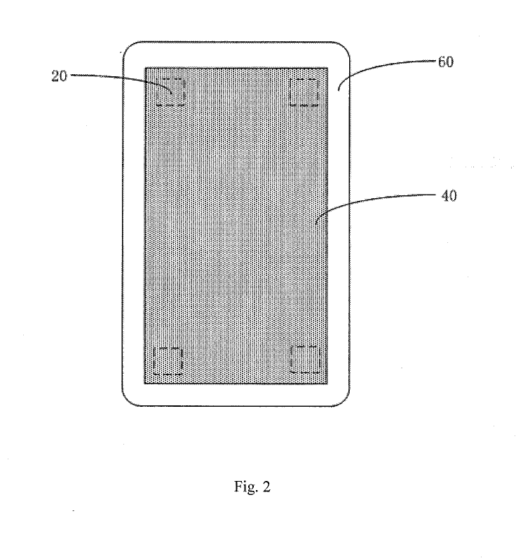

Preferably, as illustrated in FIG. 2, which is a top view of the OLED device, in the present embodiment, the display device is quadratic. FIG. 2 illustrates the display panel 40 disposed under the transparent cover plate 60, the display panel 40 includes four corners, and pressure sensors 20 are respectively disposed under the four corners. Accordingly, a magnitude of the force and the direction and position of the applied force may be judged better.

Preferably, the OLED device of the present embodiment is an AMOLED (Active Matrix Organic Light Emitting Diode) display device.

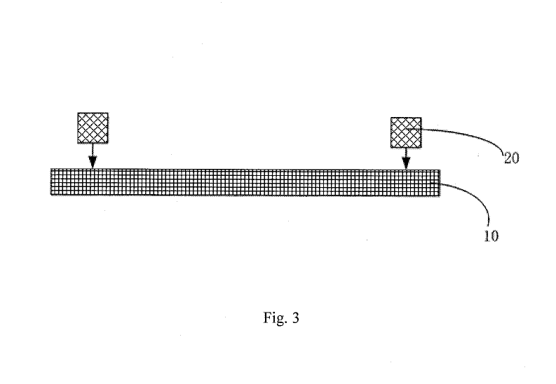

As illustrated in FIG. 3 to FIG. 5, which are drawings of manufacturing process of the OLED device of the present embodiment, the manufacturing process includes steps as follow.

In step 1A, a flexible circuit board 10 and a plurality of pressure sensors 20 are provided, and the plurality of pressure sensors 20 are adhered to an upper surface of the flexible circuit board 10, as illustrated in FIG. 3 (the arrow indicates the adhering direction, similarly hereinafter).

In step 1B, a touch screen 50 and a display panel 40 are provided, and a lower surface of the touch screen 50 is attached to an upper surface of the display panel 40.

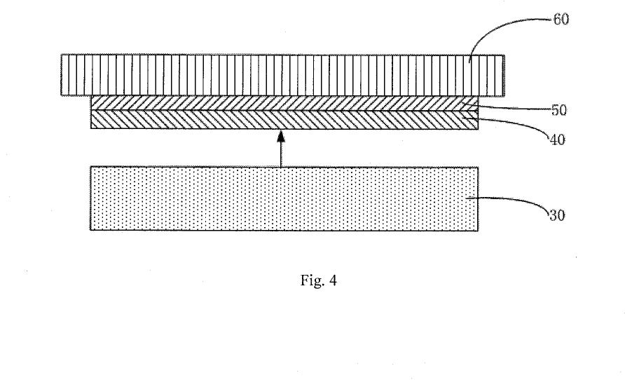

In step 1C, an adhesive layer 30 is adhered to a lower surface of the display panel 40, as illustrated in FIG. 4.

In the steps 1A, 1B, and 1C, the letters A, B and C do not represent the sequential order of the steps. That is, the steps 1A, 1B and 1C are performed separately without any particular order.

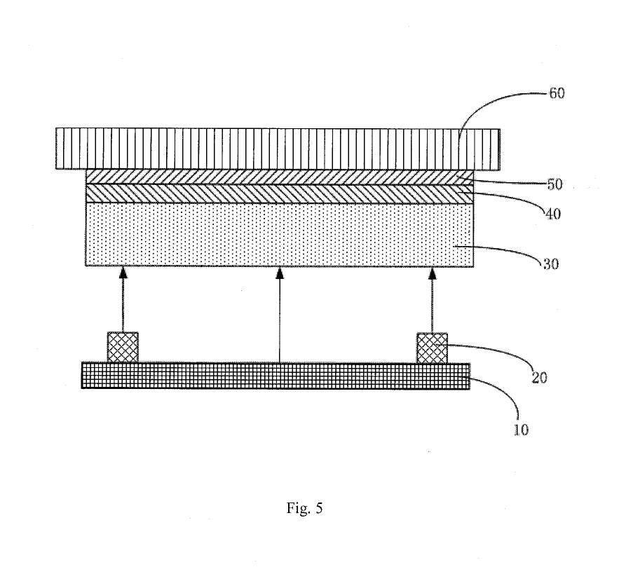

In step 2, an upper layer of the flexible circuit board 10 resulted in step 1A is adhered to a lower surface of the adhesive layer 30 resulted in step 1B, such that the plurality of pressure sensors 20 are pressed into the adhesive layer 30, thereby being embedded into the adhesive layer 30, as illustrated in FIG. 5.

### Embodiment 2

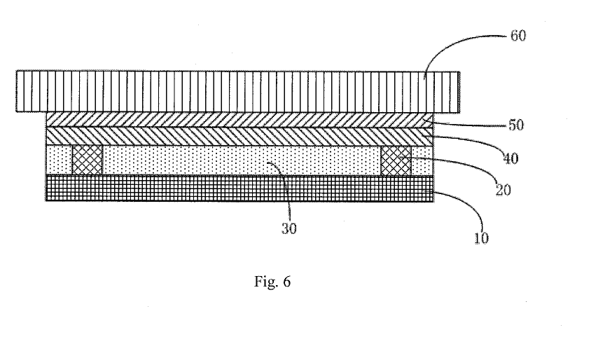

Referring to FIG. 6, which is a structural diagram of the OLED device of embodiment 2 of the present disclosure. As can be seen form FIG. 6, the OLED device of embodiment 2 differs from that of embodiment 1 in that the pressure sensor 20 is disposed in the adhesive layer 30 and is in contact with the display panel 40.

The method for manufacturing the OLED device of embodiment 2 differs from that of embodiment 1 in that: in step 2, the plurality of pressure sensors 20 are embedded into the adhesive layer 30 to direct in contact with the lower surface of the display panel 40.

Except of the foregoing, structure and manufacturing method of the OLED device of embodiment 2 are substantially identical to those of embodiment 1, and thus will not be repeated herein.

The OLED device according to the above embodiments of the present disclosure may be applied in a terminal electronic device such as a smart phone, a tablet computer, and the like. For example, the OLED device may be used in combination with a control button or a switch element of the terminal electronic device, or may be used separately by being embedded into a cover glass or inside a case of the terminal electronic device.

It should be noted that the present specification is described according to implementations, however, each implementation may involve different technical solutions. The descriptions in the present specification are provided for clarity. Those skilled in the art should regard the specification as a whole, and technical solutions in each implementation may also be combined appropriately to form other implementations that are available to those skilled in the art.

Detailed descriptions hereinabove are provided only for describing possible implementations of the present disclosure in detail. They are not provided for limiting the protection scope of the present disclosure, and all the equivalent implementations and alternatives without going beyond the technical spirit of the present disclosure are involved in the protection scope of the present disclosure.

What is claimed is:

1. An organic light emitting display (OLED) device, comprising:
a touch screen;
a display panel having an upper surface attached to a lower surface of the touch screen and a lower surface applied with an adhesive layer;
a circuit board having an upper surface adhered to the adhesive layer; and
a plurality of pressure sensors disposed in the adhesive layer.

2. The OLED device of claim 1, wherein the plurality of pressure sensors are adhered to the upper surface of the circuit board.

3. The OLED device of claim 1, wherein the display panel comprises four corners, and the pressure sensors are respectively disposed under the four corners.

4. The OLED device of claim 3, wherein lower surfaces of the four corners of the display panel are in contact with the pressure sensors.

5. The OLED device of claim 1, wherein the OLED device is an active matrix organic light emitting diode (AMOLED) display device.

6. The OLED device of claim 5, wherein the circuit board is a flexible based circuit board.

7. The OLED device of claim 1, further comprising a transparent cover plate disposed on the touch screen.

8. The OLED device of claim 7, wherein the transparent cover plate is formed of glass or acryl.

9. A method for manufacturing an organic light emitting display (OLED) device, comprising:
step 1A, providing a circuit board with a plurality of pressure sensors thereon;
step 1B, providing a display panel combined with a touch screen; and
step 2, adhering the circuit board to the display panel through an adhesive layer, such that the plurality of pressure sensors are disposed between the circuit board and the display panel and imbedded in the adhesive layer.

10. The method of claim 9, after the step 1B further comprising:
step 1C, providing the adhesive layer attached on the display panel.

11. The method of claim 9, wherein in the step 2, the plurality of pressure sensors are imbedded into the adhesive layer to direct in contact with the display panel.

12. The method of claim 9, wherein the OLED device is an AMOLED display device.

13. The method of claim 9, wherein the circuit board is a flexible based circuit board.

14. An electronic apparatus comprising an OLED device, wherein the OLED device comprises:
a touch screen;
a display panel having an upper surface attached to a lower surface of the touch screen and a lower surface applied with an adhesive layer;
a circuit board having an upper surface adhered to the adhesive layer; and
a plurality of pressure sensors disposed in the adhesive layer.

15. The electronic apparatus of claim 14, wherein the plurality of pressure sensors are adhered to the upper surface of the circuit board.

16. The electronic apparatus of claim 14, wherein the display panel comprises four corners, and the pressure sensors are respectively disposed under the four corners.

17. The electronic apparatus of claim 16, wherein lower surfaces of the four corners of the display panel are in contact with the pressure sensors.

18. The electronic apparatus of claim 14, wherein the OLED device is an active matrix organic light emitting diode (AMOLED) display device.

19. The electronic apparatus of claim 14, further comprising a transparent cover plate disposed on the touch screen.

20. The electronic apparatus of claim 19, wherein the transparent cover plate is formed of glass or acryl.
